(19) United States
(12) Patent Application Publication
(10) Pub. No.: US 2017/0141075 A1
(43) Pub. Date: May 18, 2017

(54) PROCESS OF FORMING SEMICONDUCTOR DEVICE

(71) Applicant: SUMITOMO ELECTRIC DEVICE INNOVATIONS, INC., Yokohama (JP)

(72) Inventor: Ken Osawa, Yokohama (JP)

(21) Appl. No.: 15/352,347

(22) Filed: Nov. 15, 2016

(30) Foreign Application Priority Data
Nov. 16, 2015 (JP) 2015-224138

(51) Int. Cl. H01L 23/00; B23K 1/005; B23K 1/00

(52) U.S. Cl. CPC H01L 24/83; H01L 24/75; B23K 1/0016; B23K 1/0053; H01L 2224/83048; H01L 2224/83192; H01L 2224/8323; H01L 2224/83815; H01L 2224/83007; H01L 2924/10272; H01L 2224/83805; H01L 2224/75283; H01L 2224/75251

(57) ABSTRACT

A process of forming a semiconductor device is disclosed, where the semiconductor device provides a base and a semiconductor chip that is mounted on the base through solder. The process includes steps of: (a) melting the solder by a heater that is provided within a block of a bonding apparatus, where the block mounts the base thereon and the base provides the solder thereon; (b) heating the semiconductor chip by radiation beams in advance to mount the semiconductor chip onto the base; and (c) placing the semiconductor chip onto the melted solder.

### BACKGROUND OF THE INVENTION

1. Field of the Invention

The present invention relates to a process of forming a semiconductor device, in particulate, the invention relates to a process of die-bonding a semiconductor chip on a substrate.

2. Background Arts

A die-bonding of a semiconductor chip on a substrate uses a solder pellet made of eutectic metal. Melting a solder pellet on the substrate and placing the semiconductor chip on the melted pellet, the semiconductor chip may be bonded on the substrate. A Japanese Patent laid open No. H05-166856A has disclosed a conventional technique of the die-bonding using such a solder pellet. In order to enhance bond strength of a semiconductor chip to a base material on which the semiconductor chip is to be mounted; solder is preferably and uniformly spread between the semiconductor chip and the base. In another aspect, in order to reduce thermal resistance between the semiconductor chip and the base, the solder is preferably saved in an amount thereof. Accordingly, a process of mounting the semiconductor chip onto the base first melts the solder by raising a temperature thereof higher than a melting temperature of the solder; then attaching the semiconductor chip to the solder and cooling the temperature down to the room temperature, the semiconductor chip is bonded onto the base.

However, the bonding of the semiconductor chip onto the base sometimes leaves voids in the solder. Because the voids, exactly, air in the voids, has thermal conductivity smaller than that of the solder, the heat dissipating function from the semiconductor chip to the base degrades. In particular, when the semiconductor chip has good thermal conductivity, the semiconductor chip rapidly cools down the solder when the semiconductor chip is in contact to the solder, which possibly causes voids in the solder. A silicon carbide (SiC) that is often used as a substrate for a semiconductor device primarily made of nitride semiconductor materials shows good thermal conductivity, the substrate made of SiC possibly causes the voids.

### SUMMARY OF THE INVENTION

The present invention relates to a process of forming a semiconductor device, where the semiconductor device provides a base and a semiconductor chip that is mounted on the base through solder. The process of the invention includes steps of: (a) melting the solder by a heater provided within a block of a bonding apparatus that mounts the semiconductor chip onto the base, where the block of the apparatus mounts the base thereon, and the base provides the solder thereon; (b) heating the semiconductor chip by radiation beams in advance to mount the semiconductor chip onto the base; and (c) placing the semiconductor chip onto the melted solder.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1A schematically illustrates a cross section of an apparatus for mounting a semiconductor device on a base, and FIG. 1B schematically illustrates a cross section of a semiconductor chip that provides in a back surface thereof a back metal;

FIGS. 2A and 2B show processes of mounting the semiconductor chip onto the base as heating the semiconductor chip in advance to the mounting;

FIG. 3A shows a completion of the process of mounting the semiconductor chip onto the base, and FIG. 3B magnifies the semiconductor chip mounted on the base; and

FIG. 4A shows a process of mounting the semiconductor chip onto the base, which is comparable to the process of the present invention, and FIG. 4B magnifies the semiconductor chip mounted on the base by the conventional technique.

### DESCRIPTION OF EMBODIMENT

Next, embodiment of the present invention will be described as referring to accompanying drawings. In the description of the drawings, numerals or symbols same with or similar to each other will refer to elements same with or similar to each other without duplicating explanations.

Apparatus

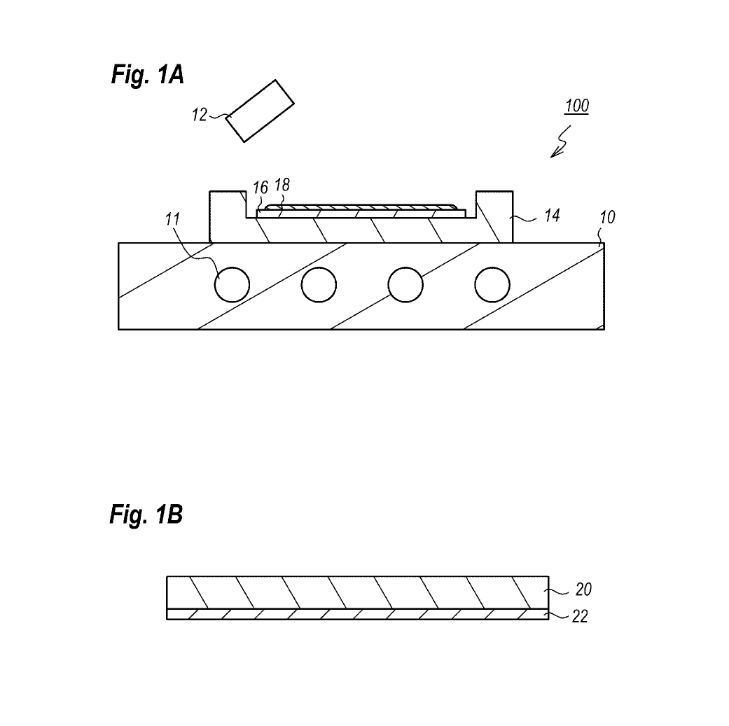

FIG. 1A schematically shows a cross section of an apparatus 100 for mounting a semiconductor device on a base 14. The apparatus 100 provides a block 10 and a radiation source 12. The block 10 may be made of copper and include a heater 11 therein. The radiation source 12, which is arranged above the block 10, radiates infrared rays onto the block 10.

The block 10 mounts a base 14 that provides in a top surface thereof a metal layer 16 accompanied with solder 18 thereon. The base 14 in a bottom surface thereof is closely in contact to a top surface of the block 10, while, the solder 18 is also closely in contact to the metal layer 16. The base 14 may be made of metal or electrically insulating material such as ceramics. In an example, the base 14 may stack metals of copper (Cu), molybdenum (Mo), and another cupper (Cu) from the bottom thereof. The metal layer 16 may be made of gold (Au). The solder 18 may be made of eutectic metal of gold-tin (AuSn). The base 14 may have a thickness of 0.1 to 5.0 mm, while, the metal layer 16 preferably has a thickness of 0.5 to 10 μm.

Semiconductor Chip

FIG. 1B schematically illustrates a cross section of a semiconductor chip 20 that provides in a back surface thereof a back metal 22. The semiconductor chip 20 may include, for instance, a filed effect transistor (FET), in a top surface thereof. Specifically, the semiconductor chip 20 includes a substrate made of, for instance, silicon carbide (SiC) with a thickness of 50 to 200 μm on which semiconductor layers constituting the FET is formed. The semiconductor layers may include a channel layer made of gallium nitride (GaN) and a barrier layer made of aluminum gallium nitride (AlGaN). The semiconductor chip 20 typically has a square or rectangular plane shape with edges of about 7 mm at most. The back metal 22 may be made of gold (Au) with a thickness of 5 to 30 μm.

Process of Forming Semiconductor Device

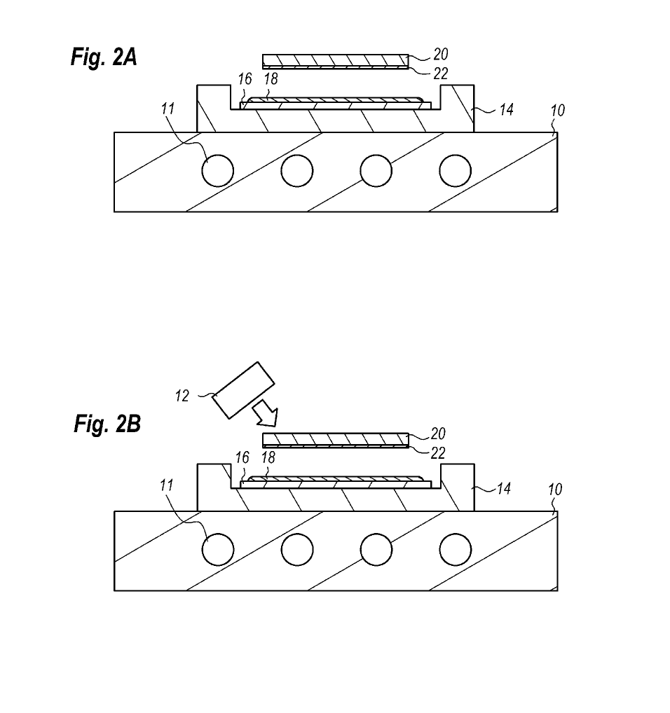

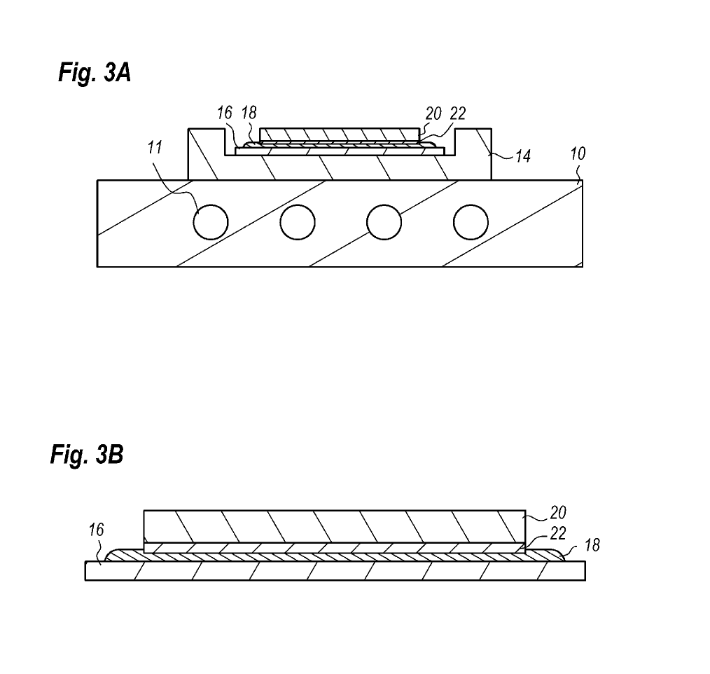

Next, a process of forming the semiconductor device according to the first embodiment will be described as referring to FIGS. 2A to 3A each showing cross sections of the semiconductor device at respective processes. FIGS. 2A to 3A omit the radiation source 18.

First, the process picks up the semiconductor chip shown in FIG. 1B by a vacuum collet or else, which is not shown in the figures, and carries the picked semiconductor chip above the solder 18. The heater 11 may heat the solder 18 provided on the top of the base 14 from the bottom thereof through the block 10. The solder melts by heat conducted from the heater through the block 10, the base 14, and the metal layer 16. Because the solder has a melting point of about 282° C., when the solder 18 is a eutectic metal of gold-tin (AuSn) with a Sn composition of 20%, the heater raises a temperature of the solder 18, exactly, a temperature of the top surface of the base 14, to around 300° C. The heating of the base 14, or the solder 18, by the heater 11 may be carried out before or after the conveyance of the semiconductor chip 20 but inevitably before the place of the semiconductor chip 20 onto the solder 18.

The radiation source 12 radiates infrared rays having wavelengths of 0.75 to 15 μm onto the semiconductor chip 20 secured above the base 14 before the placement on the base 14, which raises a temperature of the semiconductor chip 20 and the back metal 22 to 50 to 300° C. In the present embodiment, the semiconductor chip 20 is primarily made of nitride semiconductor materials that are substantially transparent for infrared rays. Accordingly, most of the infrared rays are absorbed by the back metal 22 and raises a temperature of the back metal 22, which also raises a temperature the semiconductor chip 20. During the irradiation of the semiconductor chip 20 by the radiation source 12, the heater 11 continuously heats the block 10, or the temperature of the solder 18 is kept high by the heating by the heater 11.

Then, as FIGS. 3A and 3B illustrate, the process mounts the semiconductor chip 20 onto the base 14 by attaching the back metal 22 to the solder 18. The melted solder 18 flows between the back metal 22 and the metal layer 16 and extends under a whole of the semiconductor chip 20. After the mount of the semiconductor chip 20 onto the base 14, the process stops the irradiation by the radiation source 12, then, turns off the heater 11, which solidifies the solder 18 so as to migrate the back metal 22 with the metal layer 16. Thus, the semiconductor chip 20 is mounted on the base 14.

The process of the first embodiment of the invention heats the semiconductor chip by the infrared rays provided from the radiation source 12, which raises the temperature of the semiconductor chip 20 so as to compensate a temperature difference between the semiconductor chip 20 and the solder 18. Accordingly, the heat conduction from the solder 18 to the semiconductor chip 20 may be reduced when the semiconductor chip 20 is attached to the solder 18, which suppresses a rapid solidification of the solder 18 and enhances the solder 18 to spread under the whole of the semiconductor chip 20. Thus, the voids under the semiconductor chip 20 may be effectively suppressed and the heat conduction from the semiconductor chip 20 to the base 14 may be secured. The heat generated within the semiconductor chip 20 may be effectively dissipated to the base through the back metal 22 and the solder 18. Also, the bond strength of the semiconductor chip 20 to the base 14 enhances.

The heater 11 may heat the solder 18 to a temperature higher than a melting temperature thereof. That is, the heater 11 may melt the solder 18 without irradiating the infrared rays. That is, the solder 18 is melted when the semiconductor chip 20 is placed thereon, which enhances the solder 18 to spread under the whole of the semiconductor chip 20 and prevents the voids from generating under the semiconductor chip 20.

Even when the solder 18 is unable to be melted by the heat provided from the heater 11, additional heat derived from the semiconductor chip 20 heated by the infrared rays from the radiation source 12 may melt the solder 18. However, in such a case, the solder 18 is left solidified before the mount of the semiconductor chip 20 onto the solder 18; accordingly, the solder 18 is unable to spread under the whole of the semiconductor chip 20, which possibly causes voids. The solder 18 is preferably melted before the mount of the semiconductor chip 20 onto the solder 18, that is, the semiconductor chip 20 is preferably placed onto the melted solder 18.

Also, even when the heater 11 is unable to melt the solder 18 alone, the solder 18 possibly melts by the infrared rays coming from the radiation source 12 in addition to the heat derived from the heater 11. However, conveying the semiconductor chip 20 above the base 14, the semiconductor chip 20 blocks the infrared rays, which possibly leaves the solder 18 solidified. Accordingly, the apparatus preferably heats the solder 18 to a temperature at which the solder 18 may melt. Because the heater 11 is to be stopped after the radiation source is stopped, the solder 18 is prevented from the rapid cooling, which effectively prevents the solder form causing cracks.

The apparatus of the invention may arrange the radiation source 12 so as to radiate the semiconductor chip 20 with the infrared rays. In order to radiate the semiconductor chip 20 with the infrared rays, the radiation source 12 is preferable arranged obliquely above the semiconductor chip 20, or the base 14. The radiation source 12, or a means to heat an object in noncontact, may heat the semiconductor chip 20 further uniformly compared with a case where the semiconductor chip 20 is heated by heaters directly in contact thereto. In order to further enhance the uniformity of the heating, the irradiation by the radiation source 12 is preferably started just before the mounting of the semiconductor chip 20 onto the base 14. In an alternative, the apparatus may provide a halogen lamp that radiates infrared rays having spectrum from 0.5 to 2.5 μm, which may also heat the semiconductor chip 20 in noncontact, or, hot-air may be also applicable to the apparatus. When the hot-air heats up the semiconductor chip 20, the back metal 22 is unnecessary to be provided in the back surface of the semiconductor chip 20.

When the semiconductor chip 20 implements a device operable at high power and high frequencies, typically, those devices made of nitride semiconductor materials, the substrate is preferably made of silicon carbide (SiC) that shows thermal conductivity substantially twice of that of silicon (Si). Accordingly, heat for melting the solder 18 is easily conducted to the semiconductor chip 20. The apparatus of the present invention raises the temperature of the semiconductor chip 20 by the infrared rays in advance to the placement of the chip 20 on the solder 18; accordingly, the rapid cooling of the solder 18 by the unheated semiconductor chip 20 as those of the conventional apparatus, the apparatus of the embodiment may effectively suppress or substantially prevent the solder 18 from causing the voids. Thus, because the semiconductor chip 20 may be closely in contact to the base 14, the semiconductor device of the present invention may enhance the heat dissipation from the semiconductor chip 20 to the base 14.

Because the semiconductor chip 20 of the embodiment is primarily made of nitride semiconductor materials and has a substrate made of SiC, the semiconductor chip 20 is substantially transparent for the infrared rays. Thus, the back metal 22 in the back surface of the semiconductor chip 20, which absorbs infrared rays, may be effectively heated thereby. The semiconductor chip 20 is heated by the heat conducted from the back metal 22. When the back metal primarily includes gold (Au), the infrared rays coming from the radiation source 12 preferably have spectra in a near infrared-region from 0.75 to 15 μm or in a mid-infrared region from 2.5 to 4.0 μm. The back metal 22 may be made of, except for gold (Au), copper (Cu), eutectic alloy of gold germanium (AuGe), and so on. A combination of materials for the back metal 22 with the spectra of the infrared rays becomes important. That is, the back metal 22 is necessary to be made of materials that effectively absorb infrared rays coming from the radiation source, or the radiation source 12 is necessary to provide the infrared rays having spectra absorbable by the back metal 22. The semiconductor chip 20 is necessary to be raised in the temperature thereof at least higher than a room temperature.

Comparison to Conventional Technique

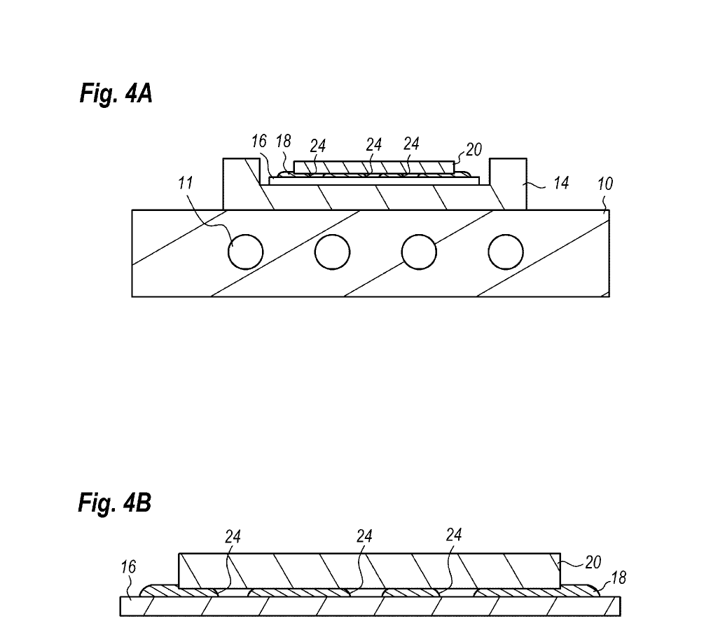

Next, a conventional technique comparable to the present embodiment will be described. FIG. 4A schematically illustrates a cross section of a semiconductor chip 20 at the process for bonding onto the base 14, and FIG. 4B magnifies the semiconductor chip 20 and the metal layer 16 onto which the semiconductor chip 20 is bonded.

As FIG. 4A indicates, the conventional technique, or a conventional apparatus does not provide the radiation source 12 and omits the back metal 22 in the semiconductor chip 20. The heater 11 in the block 10 melts the solder 18 and the semiconductor chip 20 is placed onto the melted solder 18. However, attaching the semiconductor chip 20 to the solder 18, the semiconductor chip 20 cools the solder 18 sometimes down to a temperature below melting temperature of the solder 18. Accordingly, as FIG. 4B indicates, the rapid cooling of the solder 18 possibly leaves voids 24 under the semiconductor chip 20. Saving the solder 18, the voids 24 easily occur. Also, when the substrate of the semiconductor chip 20 is made of material having good thermal conductivity, such as SiC, heat attributed to the solder 18 easily conducts to the semiconductor materials provided on the substrate, which also easily produces the voids 24. Because the voids 24, exactly, air left within the voids 24, has degraded thermal conductivity compared with that of the solder 18, the heat dissipating function of the semiconductor chip 20 degrades.

Because the embodiment of the present invention effectively prevents the voids, the heat dissipating function of the semiconductor device 100 enhances. Also, because the solder 18 is saved in an amount thereof; that is, even the process saves the solder 18, the semiconductor chip 20 may be reliably mounted on the metal layer 16, the thermal resistance of the solder 18 may be reduced and the heat dissipating function from the semiconductor chip 20 to the base 14 may be substantially kept high.

The semiconductor chip 20 includes the semiconductor layers grown on the substrate that may be made of SiC, Si, sapphire (Al₂O₃), GaN and so on. The semiconductor layers form a semiconductor active device, such as field effect transistor (FET) primarily made of nitride semiconductor materials. The nitride semiconductor materials include at least nitrogen (N), for instance, GaN, AlGaN, InGaN, InAlGaN, and so on. The semiconductor chip 20 may be made of arsenide semiconductor materials, typically, gallium arsenide (GaAs). In such a case, the semiconductor substrate is made of GaAs. Also, the semiconductor device may be other types of devices except for the FET. Although the specification concentrates the solder 18 on the type of a eutectic metal of AuSn; the solder 18 may be made of other metals, or metal alloys, such as silver (Ag), or a solder without containing lead (Pb).

While particular embodiment of the present invention have been described herein for purposes of illustration, many modifications and changes will become apparent to those skilled in the art. Accordingly, the appended claims are intended to encompass all such modifications and changes as fall within the true spirit and scope of this invention.

The present application claims the benefit of priority of Japanese Patent Application No. 2015-224138, filed on Nov. 16, 2015, which is incorporated herein by reference.

I claim:

1. A process of forming a semiconductor device that provides a base and a semiconductor chip mounted on the base through solder, comprising steps of:
melting the solder by a heater provided within a block of a bonding apparatus that mounts the semiconductor chip onto the base, the block mounting the base thereon, the base providing the solder thereon;
heating the semiconductor chip by radiation beams in advance to mount the semiconductor chip onto the base; and
placing the semiconductor chip onto the melted solder.

2. The process of claim 1,
wherein the radiation beams are infrared rays irradiated on the semiconductor chip.

3. The process of claim 2,
wherein the semiconductor chip provides a back metal to be in contact to the base,
wherein the step of heating the semiconductor chip includes a step of heating the back metal by the infrared rays.

4. The process of claim 3,
wherein the semiconductor chip further provides a substrate and semiconductor layers formed on the substrate, the substrate and the semiconductor layers being made of materials substantially transparent for the infrared rays.

5. The process of claim 3,
wherein the substrate is made of silicon carbide (SiC) and the semiconductor layers are made of nitride semiconductor materials.

6. The process of claim 2,
further comprising steps of
picking the semiconductor chip so as to face the back metal against the base;
conveying the semiconductor chip above the base; and
irradiating the semiconductor chip with the infrared rays from a top surface thereof opposite to a surface to which the back metal is formed thereon.

7. The process of claim 6,
wherein the step of melting the solder is carried out before the step of conveying the semiconductor chip.

8. The process of claim 6,
wherein the step of malign the solder is carried out after the step of conveying the semiconductor chip.

9. The process of claim 1,
wherein the step of heating the semiconductor chip by the infrared rays includes a step of heating the semiconductor chip to a temperature higher than a room temperature.

10. The process of claim 9,
wherein the step of heating the semiconductor chip includes a step of heating the semiconductor chip higher than 50 to 300° C.

11. The process of claim 1,
wherein the base provides a metal layer under the solder, and
wherein the step of melting the solder includes a step of melting the solder but leaving the metal layer as un-melted.

12. The process of claim 11,
wherein the solder is made of one of eutectic metal of gold tin (AuSn), silver (Ag), and lead (Pb) free solder.

13. The process of claim 1,
wherein the radiation source is a halogen lamp.
